(19) United States
(12) Patent Application Publication
(10) Pub. No.: US 2014/0312328 A1
(43) Pub. Date: Oct. 23, 2014

(54) METHOD OF MANUFACTURING TRANSPARENT FLEXIBLE DISPLAY DEVICE AND TRANSPARENT FLEXIBLE DISPLAY DEVICE MANUFACTURED USING THE METHOD

(71) Applicant: Samsung Display Co., Ltd., Yongin-City (KR)

(72) Inventors: Young-Sik Yoon, Seoul (KR); Sang-Jo Lee, Yongin-City (KR)

(73) Assignee: Samsung Display Co., Ltd., Yongin-City (KR)

(21) Appl. No.: 14/218,959

(22) Filed: Mar. 18, 2014

(30) Foreign Application Priority Data
Apr. 23, 2013 (KR) 10-2013-0044552

(51) Int. Cl. H01L 51/50; H01L 51/56; H01L 51/00

(52) U.S. Cl. CPC H01L 51/50; H01L 51/0014; H01L 51/0027; H01L 51/56
USPC 257/40; 438/34

(57) ABSTRACT

A method of manufacturing a transparent flexible display device includes forming a protection layer on a first surface of a transparent substrate, forming a transparent polymer layer on the protection layer, forming an amorphous silicon pattern on the transparent polymer layer, irradiating a first laser on the amorphous silicon pattern to dehydrogenate the amorphous silicon pattern, irradiating a second laser on the dehydrogenated amorphous silicon pattern to form a polycrystalline silicon pattern, forming a metal pattern on the polycrystalline silicon pattern, forming a display element electrically connected to the metal pattern, and irradiating a third laser on a second surface of the transparent substrate to separate the transparent polymer layer from the protection layer.

### CROSS-REFERENCE TO RELATED APPLICATION

This application claims priority to and the benefit of Korean Patent Application No. 10-2013-0044552, filed on Apr. 23, 2013, the entire contents of which is incorporated by reference herein.

### BACKGROUND

1. Field

Example embodiments of the present invention relate to a method of manufacturing a display device and a display device manufactured using the method.

2. Description of the Related Art

An organic light emitting diode (“OLED”) element may include a layer of organic materials between two electrodes, that is, an anode and a cathode. Positive holes from the anode may be connected with electrons from the cathode in the organic layer between the anode and the cathode to emit light. The OLED element may have a variety of features such as a wide viewing angle, a rapid response speed, relatively thin thickness, and low power consumption.

According to recently developed display technologies, a display device may be manufactured to be flexible using the OLED elements. Also, a display device may be manufactured to be entirely transparent.

A switching element to control the OLED element may include a semiconductor pattern. When the semiconductor pattern includes poly-silicon instead of amorphous silicon, electronic properties of the semiconductor pattern may be improved. It may be desirable to provide heat energy to an amorphous silicon pattern to remove the hydrogen component of the amorphous silicon pattern. Then, it may also be desirable to crystallize the amorphous silicon pattern from which the hydrogen component has been removed, to form a poly-silicon pattern. Furthermore, it may be desirable to use a relatively rigid supporting substrate to stably position the OLED element on a flexible substrate.

However, the flexible substrate in a transparent display device may be vulnerable to a high temperature which is applied during a dehydrogenation process of the amorphous silicon pattern. Accordingly, it may be difficult to develop a transparent flexible display device including a poly-silicon pattern to improve electronic properties of the semiconductor pattern.

Also, the flexible substrate may be physically damaged when separating the flexible substrate from the supporting substrate. Furthermore, optical properties of the flexible substrate may be affected adversely during the separation process. Accordingly, transmissivity or yield rates of the transparent flexible display device may be decreased.

### SUMMARY

One or more example embodiments of the present invention provide a method of manufacturing a transparent flexible display device capable of separating a flexible substrate from a supporting substrate while reducing damage to the flexible substrate.

Also, another example embodiment of the present invention provides a transparent flexible display device manufactured using the method of manufacturing the transparent flexible display device.

In an example embodiment of a method of manufacturing a transparent flexible display device according to the present invention, the method includes forming a protection layer on a first surface of a transparent substrate, forming a transparent polymer layer on the protection layer, forming an amorphous silicon pattern on the transparent polymer layer, irradiating a first laser on the amorphous silicon pattern to dehydrogenate the amorphous silicon pattern, irradiating a second laser on the dehydrogenated amorphous silicon pattern to form a polycrystalline silicon pattern, forming a metal pattern on the polycrystalline silicon pattern, forming a display element electrically connected to the metal pattern, and irradiating a third laser on a second surface of the transparent substrate to separate the transparent polymer layer from the protection layer.

The protection layer may include indium tin oxide.

The transparent polymer layer may include transparent polyimide.

A thickness of the protection layer may be in a range of about 100 nanometers to 200 nanometers.

An energy density of the first laser may be in a range of about 300 mJ/cm² to 340 mJ/cm².

A number of times that the first laser is irradiated on the amorphous silicon pattern are in a range of 10 to 40.

An energy density of the third laser may be in a range of about 180 mJ/cm² to 450 mJ/cm².

In an example embodiment, the metal pattern may include a gate electrode overlapping the polycrystalline silicon pattern, a source electrode contacting a portion of the polycrystalline silicon pattern, the source electrode overlapping a first end portion of the gate electrode, and a drain electrode contacting another portion of the polycrystalline silicon pattern, the drain electrode overlapping a second end portion of the gate electrode.

In an example embodiment, the display element may include an organic light emitting element.

In an example embodiment, the organic light emitting element may include a pair of electrode layers facing each other, and an intermediate layer disposed between the electrode layers.

In an example embodiment of a transparent flexible display device according to the present invention, the transparent flexible display device includes a polycrystalline silicon pattern disposed on a transparent polymer layer, the transparent polymer layer being attached to a transparent substrate with a protection layer interposed therebetween, a metal pattern disposed on the polycrystalline silicon pattern, and a display element electrically connected to the metal pattern, wherein the transparent polymer layer is separated from the protection layer by irradiation of an excimer laser after the polycrystalline silicon pattern, the metal pattern, and the display element are formed on the transparent polymer layer.

In an example embodiment, the protection layer may include indium tin oxide.

In an example embodiment, a thickness of the protection layer may be in a range of about 100 nanometers to 200 nanometers.

In an example embodiment, the transparent polymer layer may include transparent polyimide.

In an example embodiment, the excimer laser may have an energy density in a range of about 180 mJ/cm² to 450 mJ/cm².

In an example embodiment, the polycrystalline silicon pattern may be formed by dehydrogenation through irradiating a first laser having a first energy density in a range of about 300 mJ/cm² to 340 mJ/cm² on an amorphous silicon pattern, and crystallization through irradiating a second laser having a second energy density on the amorphous silicon pattern.

In an example embodiment, the metal pattern may include a gate electrode overlapping the polycrystalline silicon pattern, a source electrode contacting a portion of the polycrystalline silicon pattern, the source electrode overlapping a first end portion of the gate electrode, and a drain electrode contacting another portion of the polycrystalline silicon pattern, the drain electrode overlapping a second end portion of the gate electrode.

In an example embodiment, the display element may include an organic light emitting element.

In an example embodiment, the organic light emitting element may include a pair of electrode layers facing each other, and an intermediate layer disposed between the electrode layers.

In an example embodiment, the transparent flexible display device may further include an encapsulating substrate facing the transparent polymer layer.

According to one or more example embodiments of the method of manufacturing a transparent flexible display device and the transparent flexible display device manufactured using the method, the flexible substrate may include transparent polyimide, and the amorphous silicon pattern may be dehydrogenated by an annealing process using irradiation or radiation) of a laser with a desired energy density, thereby implementing the transparent flexible display device having the poly-silicon pattern on the transparent flexible substrate.

Also, the transparent flexible display device may include a protection layer between the supporting substrate and the flexible substrate, thereby reducing chemical or optical damage to the flexible substrate during the separation process of the supporting substrate from the flexible substrate.

### BRIEF DESCRIPTION OF THE DRAWINGS

The above and other features and aspects of the present invention will become more apparent by describing in further detail example embodiments thereof with reference to the accompanying drawings, in which:

FIG. 1 is a cross-sectional view illustrating a transparent flexible display device according to an example embodiment of the present invention;

FIGS. 2A, 2B, 2C, 2D, 2E, 2F, 2G, 2H, 2I, 2J, and 2K are cross-sectional views illustrating a method of manufacturing the transparent flexible display device shown in FIG. 1;

FIG. 3 is a graph illustrating variations of an amount of hydrogen in an amorphous silicon pattern according to energy density and a number of occurrences of irradiation of a laser on the amorphous silicon pattern shown in FIG. 2C; and

FIG. 4 is a graph illustrating transmissivities of the transparent flexible display device according to wavelengths of a laser irradiated on the protection layer shown in FIG. 2J.

### DETAILED DESCRIPTION

Hereinafter, example embodiments of the present invention will be described in further detail with reference to the accompanying drawings.

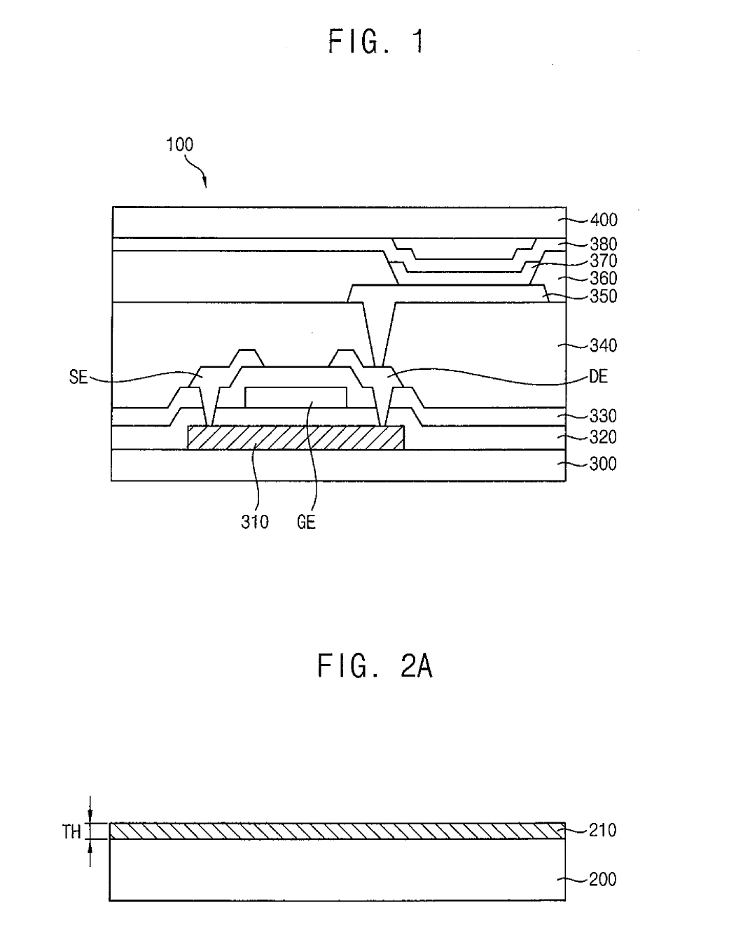

FIG. 1 is a cross-sectional view illustrating a transparent flexible display device according to an example embodiment of the present invention.

Referring to FIG. 1, a transparent flexible display device 100 according to the present embodiment of the present invention includes a transparent flexible substrate 300, a poly-crystalline silicon (hereinafter, “poly-silicon”) pattern 310, a metal pattern, a display element and an encapsulating substrate 400. The metal pattern may include a gate electrode GE, a source electrode SE and a drain electrode DE. The transparent flexible display device 100 may further include a gate insulation layer 320 and an inorganic insulation layer 330 on the poly-silicon pattern 310. Also, the transparent flexible display device 100 may further include an organic insulation layer 340 and a pixel defining pattern 360. The display element may be disposed on the organic insulation layer 340. The display element may include a first electrode 350, an intermediate layer 370 and a second electrode 380. The pixel defining pattern 360 may be disposed on the first electrode 350.

Although a thin film transistor in the transparent flexible display device 100 has a top-gate structure shown in FIG. 1, the structure of the thin film transistor in the transparent flexible display device according to example embodiments of the present invention is not limited thereto. For example, the thin film transistor in the transparent flexible display device may have a bottom-gate structure.

In one embodiment, the transparent flexible substrate 300 includes a transparent insulation material. For example, the transparent flexible substrate 300 may include transparent polyimide. The polyimide may have a variety of features such as, for example, high physical strength and relatively high thermal resistance compared to other polymers. Thus, the transparent flexible substrate 300 including the transparent polyimide may stably support the metal pattern and the display element.

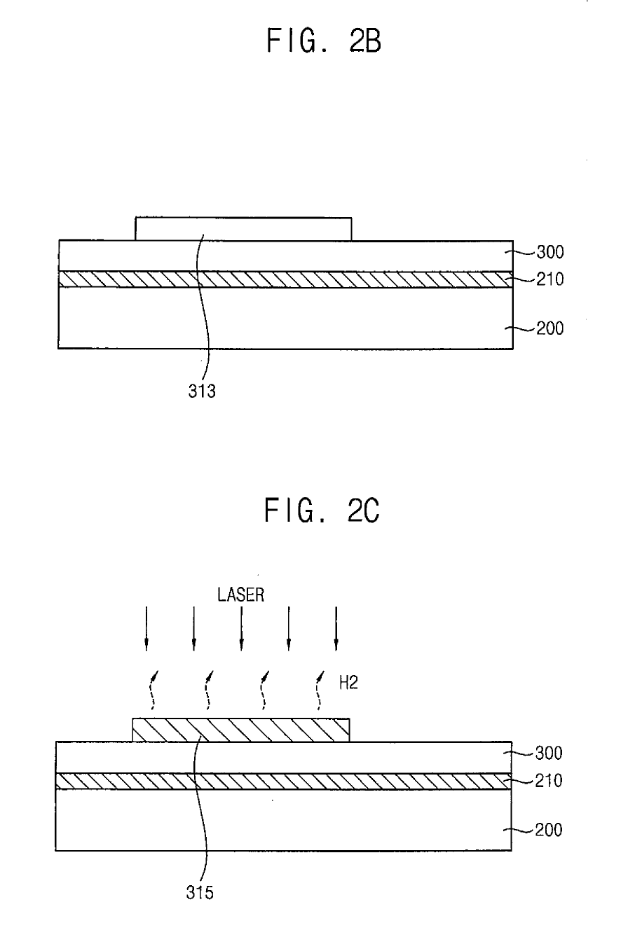

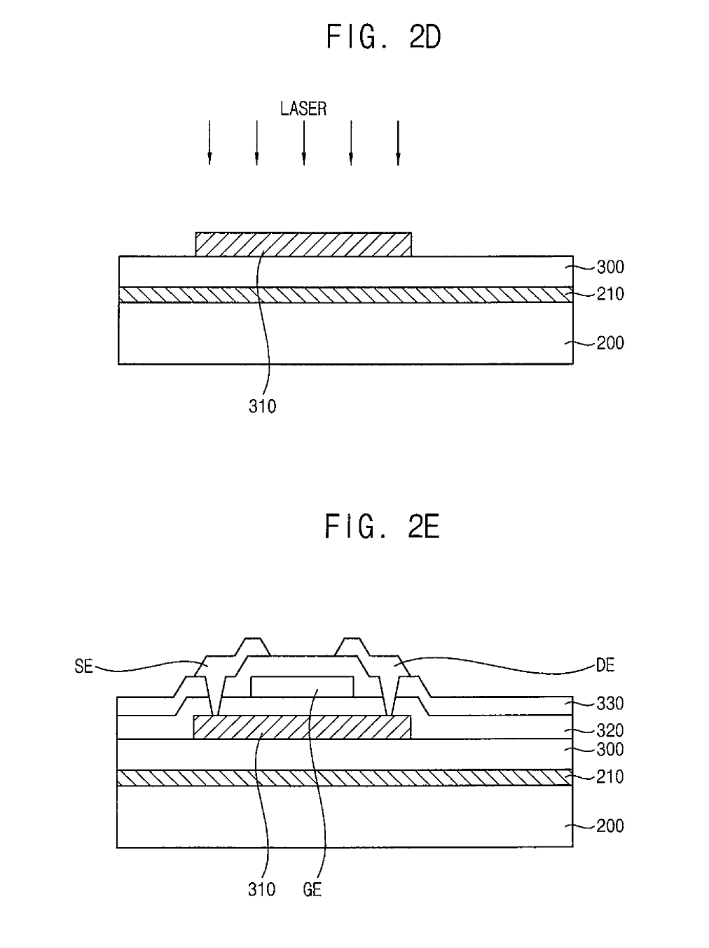

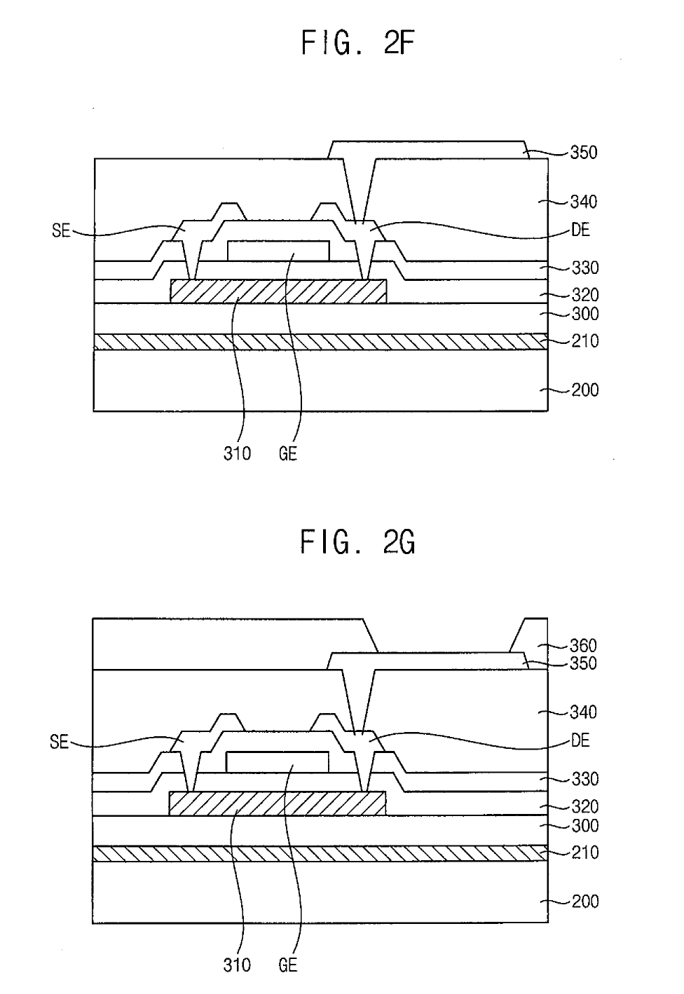

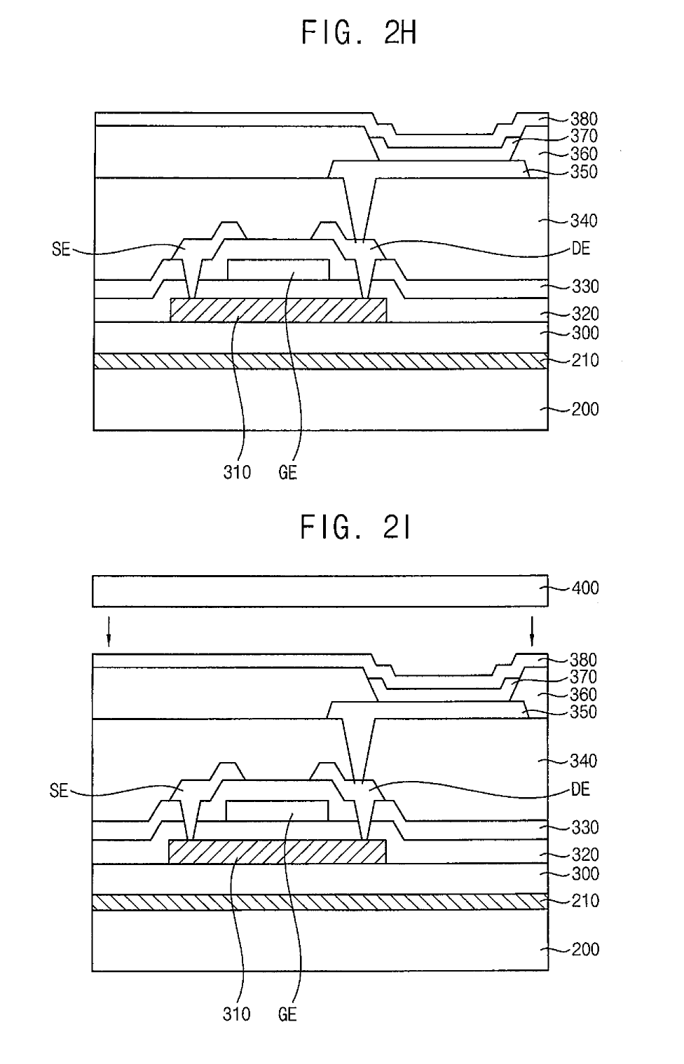

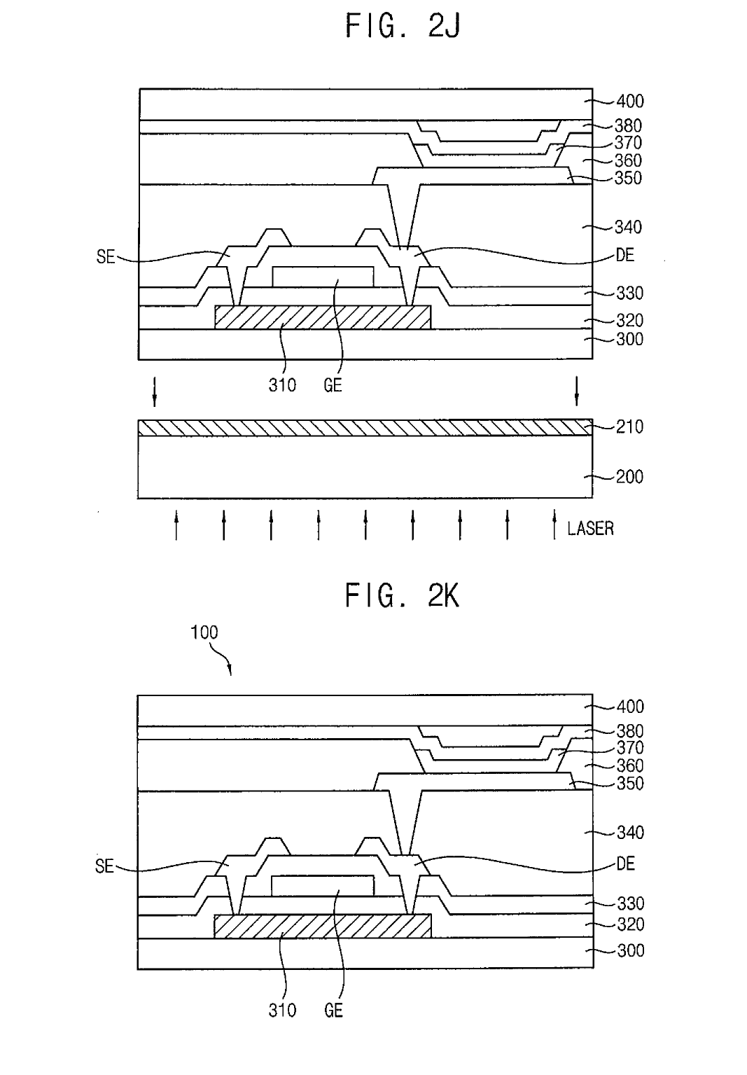

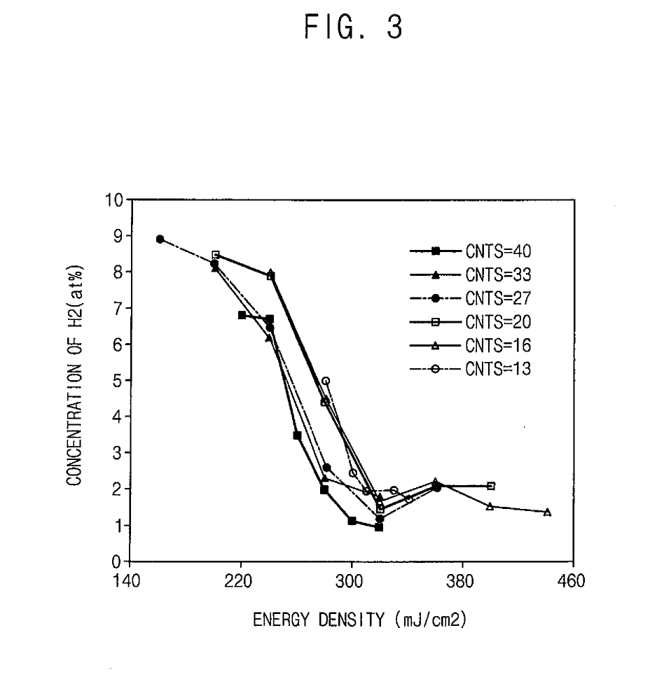

The transparent flexible substrate 300 may be provided with a transparent substrate 200 and a protection layer 210 attached thereto to position the metal pattern and the display element. After the metal pattern and the display element are disposed on the transparent flexible substrate 300, the transparent substrate 200 and the protection layer 210 may be separated from the transparent flexible substrate 300. The attaching process and the separating process will be described in further detail referring to FIGS. 2A 2B, 2C, 2D, 2E, 2F, 2G, 2H, 2I, 2J, and 2K.

The poly-silicon pattern 310 may include poly-silicon. The poly-silicon may be formed by a dehydrogenation process of amorphous silicon and by a subsequent crystallization process. For example, during the dehydrogenation process and the crystallization process, the poly-silicon may be formed by a low temperature poly-silicon (“LTPS”) process using a temperature of about 300 degrees Celsius or higher. On the other hand, transparent polyimide of the transparent flexible substrate 300, unlike opaque polyimide, may be chemically or optically damaged by a heat under the high temperature during the LTPS process. Also, when an amount of hydrogen (H₂) is not sufficiently reduced during the dehydrogenation process to reduce (or to prevent) the damage to the transparent polyimide, hydrogen that remains in the transparent polyimide may react to the heat, thereby damaging the poly-silicon pattern 310 during the subsequent crystallization process.

Therefore, in an example embodiment of a method of manufacturing the transparent flexible display device, an excimer laser having a suitable energy density (e.g., a predetermined energy density) may be used in the dehydrogenation process to reduce damage to the transparent polyimide of the transparent flexible substrate 300 and to stably form the poly-silicon from the amorphous silicon. Further detailed description on the dehydrogenation process will follow, referring to FIGS. 2C and 2D.

The gate insulation layer 320 may be disposed on the poly-silicon pattern 310. The gate insulation layer 320 may entirely cover the poly-silicon pattern 310. The gate insulation layer 320 may include, for example, silicon oxide, silicon nitride, etc.

The gate electrode GE may be disposed on the gate insulation layer 320 and may overlap the poly-silicon pattern 310. For example, the gate electrode GE may overlap a center portion of the poly-silicon pattern 310. The gate electrode GE may include, for example, aluminum (Al), chromium (Cr), nickel (Ni), molybdenum (Mo), tungsten (W), magnesium (Mg), or their alloys, etc. Also, the gate electrode GE may have a single-layered or multiple-layered structure.

The inorganic insulation layer 330 may be disposed on the gate electrode GE and may entirely cover the gate electrode GE. The inorganic layer 330 may include, for example, silicon oxide, silicon nitride, etc.

The source electrode SE may be electrically connected to the poly-silicon pattern 310 through a first contact hole formed in the gate insulation layer 320 and the inorganic insulation layer 330. For example, the source electrode SE may contact a first end portion of the poly-silicon pattern 310. Also, the source electrode SE may partially overlap a first end portion of the gate electrode GE.

The drain electrode DE may be electrically connected to the poly-silicon pattern 310 through a second contact hole formed in the gate insulation layer 320 and the inorganic insulation layer 330. For example, the drain electrode DE may contact a second end portion of the poly-silicon pattern 310. Also, the drain electrode DE may partially overlap a second end portion of the gate electrode GE.

The organic insulation layer 340 may be disposed on the inorganic insulation layer 330 on which the source electrode SE and the drain electrode DE are formed. For example, the organic insulation layer 340 may have a substantially flat surface.

The first electrode 350 may be disposed on the organic insulation layer 340. The first electrode 350 may be electrically connected to the drain electrode DE. The first electrode 350 may be formed of a transparent electrode. For example, the first electrode 350 may include indium zinc oxide (IZO), indium tin oxide (ITO), zinc oxide (ZnOx), tin oxide (SnOx), etc. In the present embodiment of the transparent flexible display device, the first electrode 350 may provide positive holes as an anode.

The pixel defining pattern 360 may be disposed on the organic insulation layer 340 on which the first electrode 350 is formed. The pixel defining pattern 360 may partially overlap two end portions of the first electrode 350.

The intermediate layer 370 may be disposed on the first electrode 350. The intermediate layer 370 may sequentially include a hole injection layer (“HIL”), a hole transfer layer (“HTL”), an emission layer (“EML”), an electron transfer layer (“ETL”) and an electron injection layer (“EIL”). The first electrode 350 provides positive holes to the HIL and the HTL. The second electrode 380 provides electrons to the ETL and the EIL. The positive holes are connected with the electrons in the EML to generate light having a desired wavelength. For example, the display element may include light emitting materials that generate red light, green light, blue light, etc. Alternatively, the display element may include a plurality of light emitting materials, each having a different wavelength or a mixture of these light emitting materials.

The second electrode 380 may be disposed on the intermediate layer 370. The second electrode 380 may overlap with the pixel defining pattern 360. The second electrode 380 may include substantially the same material as that of the first electrode 350. For example, the second electrode 380 may include indium zinc oxide (IZO), indium tin oxide (ITO), zinc oxide (ZnOx), tin oxide (SnOx), etc. In the present embodiment of the transparent flexible display device, the second electrode 380 may provide electrons as a cathode.

The encapsulating substrate 400 may face the transparent flexible substrate 300 to encapsulate the display element. The encapsulating substrate 400 may include a transparent insulation material. The encapsulating substrate 400 may have substantially the same material as that of the transparent flexible substrate 300. For example, the encapsulating substrate 400 may include transparent polyimide.

FIGS. 2A, 2B, 2C, 2D, 2E, 2F, 2G, 2H, 2I, 2J, and 2K are cross-sectional views illustrating a method of manufacturing the transparent flexible display device shown in FIG. 1. FIG. 3 is a graph illustrating variations of an amount of hydrogen in an amorphous silicon pattern according to energy density and occurrences (e.g., times) of irradiation of a laser on the amorphous silicon pattern shown in FIG. 2C.

Referring to FIG. 2A, in a method of manufacturing the transparent flexible display device 100 according to the present embodiment, a transparent substrate 200 and a protection layer 210 on the transparent substrate 200 are used as supporting members. For example, the transparent flexible substrate, the metal pattern or the display element may be disposed on the transparent substrate 200 on which the protection layer 210 is formed.

The transparent substrate 200 may include, for example, a glass substrate, a quartz substrate, etc. The transparent substrate 200 may include materials having high strength and high thermal resistance.

The protection layer 210 may have a desired thickness TH. The protection layer 210 may be disposed on a surface of the transparent substrate 200. The thickness TH of the protection layer 210 may be substantially in a range of about 100 nanometers to about 200 nanometers. The thickness TH of the protection layer 210 may be properly determined so that degradation in transmissivity of the transparent flexible substrate 300 may be reduced when a laser is irradiated on the transparent flexible substrate 300. The protection layer 210 may include, for example, indium tin oxide (ITO), etc. The ITO component in the protection layer 210 may absorb light having a wavelength (e.g., a predetermined wavelength), which will be described in further detail referring to FIG. 2J.

Referring to FIG. 2B, the transparent flexible substrate 300 may be disposed on the transparent substrate 200 on which the protection layer 210 is formed. An amorphous silicon pattern 313 having a desired width may be disposed on the transparent flexible substrate 300.

The transparent flexible substrate 300 may include transparent polyimide. The transparent polyimide may have a variety of characteristics such as, for example, high physical strength and relatively high thermal resistance compared to other polymers. The amorphous silicon pattern 313 may include hydrogen (H₂) at some amount (in atomic percentage unit). The amorphous silicon pattern 313 may be formed by, for example, a chemical vapor deposition (“CVD”) on the transparent flexible substrate 300.

Referring to FIGS. 2B, 2C and 3, a laser (e.g., a laser having a predetermined wavelength) may be irradiated on the amorphous silicon pattern 313 to form a dehydrogenated amorphous silicon pattern 315 by an annealing process. The laser may be irradiated from excimers of such as, for example, XeCl, KrF, ArF, etc. The excimer laser may have a predetermined energy density. For example, the energy density of the excimer laser may lie within a range of about 300 mJ/cm² to about 340 mJ/cm².

Table 1 represents an atomic concentration (a %) of hydrogen in the amorphous silicon pattern 313 on which an excimer laser having a predetermined energy density is irradiated according to a set number of irradiation occurrences (e.g., a predetermined number of irradiation occurrences).

TABLE 1

| | |
|---|---|
| Energy | |
| density | Number of irradiation occurrences |

| (mJ/cm²⁾ | 40 | 33 | 27 | 20 | 16 | 13 |
|---|---|---|---|---|---|---|
| 160 | | | 8.9 | | | |
| 200 | | 8.12 | 8.23 | 8.47 | | |
| 220 | 6.81 | | | | | |
| 240 | 6.69 | 6.17 | 6.49 | 7.9 | 8.01 | |
| 260 | 3.44 | | | | | |
| 280 | 1.96 | 2.25 | 2.6 | 4.37 | 4.51 | 4.98 |
| 290 | | | | | | 3.92 |
| 300 | 1.12 | | | | | 2.43 |
| 310 | | | | | | 1.94 |
| 320 | 0.95 | 1.81 | 1.2 | 1.44 | 1.62 | 1.87 |
| 330 | | | | | | 1.95 |
| 340 | | | | | | 1.71 |
| 360 | | | 2.01 | 2.06 | 2.24 | |
| 400 | | | | 2.06 | 1.53 | |
| 440 | | | | | 1.38 | |

Referring to FIG. 3 and Table 1, an amount of hydrogen in the amorphous silicon pattern 313 may be lower after the excimer laser having a relatively high energy density is irradiated a small number of times (referred to as “CNTS”) compared to a case when the excimer laser having a relatively low energy density is irradiated a large number of times (“CNTS”). For example, the amorphous silicon pattern 313 may be more dehydrogenated after the excimer laser having a relatively high energy density is irradiated a small number of times. However, the amorphous silicon pattern 313 may be less dehydrogenated after an excimer laser having an overly high energy density is irradiated. For example, the amount of hydrogen in the amorphous silicon pattern 313 after being exposed to an excimer laser having 360 mJ/cm² in energy density is greater than the amount of hydrogen in the amorphous silicon pattern 313 after being exposed to an excimer laser having 320 mJ/cm² in energy density, even after irradiating the excimer laser the same number of times in each example (e.g., 20 times each).

As mentioned above, the energy density and the number of irradiation occurrences (e.g., times) of the excimer laser may be properly determined so that the amorphous silicon pattern 313 may be well dehydrogenated. For example, the amorphous silicon pattern 313 may be irradiated by an excimer laser having an energy density in a range of about 300 mJ/cm² to about 340 mJ/cm², and the amorphous silicon pattern 313 may be irradiated about 10 times to about 40 times during the dehydrogenation process. For example, the amorphous silicon pattern 313 may be irradiated by an excimer laser having an energy density of about 320 mJ/cm² at about 10 times to about 40 times during the dehydrogenation process.

Referring to FIG. 2D, another laser having a desired energy density may be irradiated on the dehydrogenated amorphous silicon pattern 315 to form a poly-silicon pattern 310. In the crystallization process, a laser having an energy density used in a conventional LTPS process may be irradiated at a proper number of irradiation occurrences. For example, an excimer laser having an energy density in a range of about 400 mJ/cm² to about 700 mJ/cm² may be irradiated at least one time during the crystallization process.

Referring to FIG. 2E, a gate insulation layer 320, a gate electrode GE, an inorganic insulation layer 330, a source electrode SE and a drain electrode DE may be sequentially disposed on the transparent flexible substrate 300 on which the poly-silicon pattern 310 is formed. The source electrode SE and the drain electrode DE may be electrically connected to the poly-silicon pattern 310 through contact holes.

Referring to FIG. 2F, the organic insulation layer 340 may be disposed on the transparent flexible substrate 300 on which the source electrode SE and the drain electrode DE are formed. Then, a first electrode 350 may be formed on the organic insulation layer 340. The first electrode 350 may be electrically connected to the drain electrode DE through a contact hole at the organic insulation layer 340.

Referring to FIGS. 2G and 2H, the pixel defining pattern 360 may be disposed on the transparent flexible substrate 300 on which the first electrode 350 is formed. Then, the intermediate layer 370 and the second electrode 380 may be sequentially formed on the transparent flexible substrate 300 on which the pixel defining pattern 360 is formed. The intermediate layer 370 may include the hole injection layer (“HIL”), the hole transport layer (“HTL”), the emission layer (“EML”), the electron transport layer (“ETL”) and/or the electron injection layer (“EIL”). The first electrode 350, the intermediate layer 370 and the second electrode 380 may form an organic light emitting element.

Referring to FIG. 2I, the encapsulating substrate 400 may be disposed on the transparent flexible substrate 300 on which the organic light emitting element is formed. The encapsulating substrate 400 may encapsulate the organic light emitting element by, for example, a conventional thin film encapsulation method.

Referring to FIGS. 2J and 2K, a laser having a desired energy density may be irradiated on the other surface of the transparent substrate 200 to separate the transparent flexible substrate 300 from the protection layer 210. The protection layer 210 may include indium tin oxide (ITO). The laser may have a predetermined energy density so that the transparent flexible substrate 300 may be separated from the protection layer 210.

The laser used during the separation process may have an energy density in a range of about 180 mJ/cm² to about 450 mJ/cm².

When the protection layer 210 includes indium tin oxide (ITO), the ITO component may reduce chemical or optical damage to the transparent flexible substrate 300 from the laser used in the separation process. For example, the ITO component may absorb light having a desired wavelength corresponding to the wavelength of the laser used in the separation process, thereby reducing degradation in transmissivity of the transparent flexible substrate 300 due to such effects as, for example, haze or deformation.

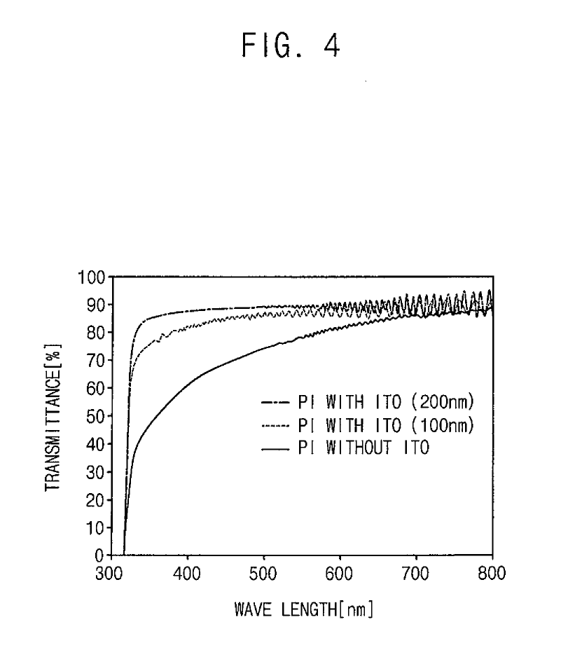

FIG. 4 is a graph illustrating transmissivities of the transparent flexible display device according to wavelengths of a laser irradiated on the protection layer shown in FIG. 2J.

Referring to FIGS. 2J and 4, the transparent flexible substrate 300 including transparent polyimide (referred to as “PI”) and separated from the transparent substrate 200 by a laser having a wavelength of about 400 nanometers may have 60% transmissivity when a protection layer is not disposed between the transparent flexible substrate 300 and the transparent substrate 200. However, the transparent flexible substrate 300 may be separated from the transparent substrate 200 by a laser having a wavelength of about 400 nanometers and retain more than about 80% transmissivity when the protection layer 210 including indium tin oxide (ITO) is disposed between the transparent flexible substrate 300 and the transparent substrate 200. Furthermore, the transmissivity of a transparent flexible substrate 300 separated from the protection layer 210 and having a thickness of about 200 nanometers may be substantially greater than the transmissivity of a transparent flexible substrate 300 separated from the protection layer 210 having a thickness of about 100 nanometers.

Although the protection layer 210 is directly disposed on the transparent substrate 200 in FIGS. 2A, 2B, 2C, 2D, 2E, 2F, 2G, 2H, 2I, and 2J, the location of the protection layer 210 on the transparent substrate 200 is not limited thereto. For example, a plurality of additional transparent layers may be formed on the transparent substrate 200, and the protection layer 210 may be formed on the additional transparent layers, and then the transparent flexible substrate 300 may be formed on the protection layer 210.

As mentioned above, according to one or more example embodiments of the method of manufacturing a transparent flexible display device and the transparent flexible display device manufactured using the method, the flexible substrate may include transparent polyimide, and the amorphous silicon pattern may be dehydrogenated by an annealing process using a laser irradiated with a desired energy density, thereby implementing the transparent flexible display device having the poly-silicon pattern on the transparent flexible substrate.

Also, the transparent flexible display device may include a protection layer between the supporting substrate and the flexible substrate, thereby reducing chemical or optical damage to the flexible substrate during the separation process of the supporting substrate from the flexible substrate.

Example embodiments of the present invention may be applied to any electronic device including a transparent flexible display device. For example, example embodiments of the present invention may be applied to a television, a computer monitor, a notebook, a digital camera, a cellular phone, a smartphone, a tablet computer, a PDA, a PMP, an MP3 player, a navigation system, a video camera recorder, mobile game consoles, etc.

The foregoing is illustrative of example embodiments and is not to be construed as limiting thereof. Although a few example embodiments have been described, those skilled in the art will readily appreciate that many modifications are possible in example embodiments without materially departing from the novel teachings and aspects of the present invention. Accordingly, all such modifications are intended to be included within the scope of example embodiments as defined in the claims. In the claims, means-plus-function clauses are intended to cover the structures described herein as performing the recited function and, not only structural equivalents, but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims, and equivalents thereof.

What is claimed is:

1. A method of manufacturing a transparent flexible display device, the method comprising:
forming a protection layer on a first surface of a transparent substrate;
forming a transparent polymer layer on the protection layer;
forming an amorphous silicon pattern on the transparent polymer layer;
irradiating a first laser on the amorphous silicon pattern to dehydrogenate the amorphous silicon pattern;
irradiating a second laser on the dehydrogenated amorphous silicon pattern to form a polycrystalline silicon pattern;
forming a metal pattern on the polycrystalline silicon pattern;
forming a display element electrically connected to the metal pattern; and
irradiating a third laser on a second surface of the transparent substrate to separate the transparent polymer layer from the protection layer.

2. The method of claim 1, wherein the protection layer comprises indium tin oxide.

3. The method of claim 1, wherein the transparent polymer layer comprises transparent polyimide.

4. The method of claim 1, wherein a thickness of the protection layer is in a range of about 100 nanometers to 200 nanometers.

5. The method of claim 1, wherein an energy density of the first laser is in a range of about 300 mJ/cm² to 340 mJ/cm².

6. The method of claim 5, wherein a number of times that the first laser is irradiated on the amorphous silicon pattern are in a range of 10 to 40.

7. The method of claim 1, wherein an energy density of the third laser is in a range of about 180 mJ/cm² to 450 mJ/cm².

8. The method of claim 1, wherein the metal pattern comprises:
a gate electrode overlapping the polycrystalline silicon pattern;
a source electrode contacting a portion of the polycrystalline silicon pattern, the source electrode overlapping a first end portion of the gate electrode; and
a drain electrode contacting another portion of the polycrystalline silicon pattern, the drain electrode overlapping a second end portion of the gate electrode.

9. The method of claim 1, wherein the display element comprises an organic light emitting element.

10. The method of claim 9, wherein the organic light emitting element comprises:
a pair of electrode layers facing each other; and
an intermediate layer disposed between the electrode layers.

11. A transparent flexible display device comprising:
a polycrystalline silicon pattern disposed on a transparent polymer layer, the transparent polymer layer being attached to a transparent substrate with a protection layer interposed therebetween;
a metal pattern disposed on the polycrystalline silicon pattern; and
a display element electrically connected to the metal pattern,
wherein the transparent polymer layer is separated from the protection layer by irradiation of an excimer laser after the polycrystalline silicon pattern, the metal pattern, and the display element are formed on the transparent polymer layer.

12. The transparent flexible display device of claim 11, wherein the protection layer comprises indium tin oxide.

13. The transparent flexible display device of claim 11, wherein a thickness of the protection layer is in a range of about 100 nanometers to 200 nanometers.

14. The transparent flexible display device of claim 11, wherein the transparent polymer layer comprises transparent polyimide.

15. The transparent flexible display device of claim 11, wherein the excimer laser has an energy density in a range of about 180 mJ/cm² to 450 mJ/cm².

16. The transparent flexible display device of claim 11, wherein the polycrystalline silicon pattern is formed by:
dehydrogenation through irradiating a first laser having a first energy density in a range of about 300 mJ/cm² to 340 mJ/cm² on an amorphous silicon pattern; and
crystallization through irradiating a second laser having a second energy density on the amorphous silicon pattern.

17. The transparent flexible display device of claim 11, wherein the metal pattern comprises:
a gate electrode overlapping the polycrystalline silicon pattern;
a source electrode contacting a portion of the polycrystalline silicon pattern, the source electrode overlapping a first end portion of the gate electrode; and
a drain electrode contacting another portion of the polycrystalline silicon pattern, the drain electrode overlapping a second end portion of the gate electrode.

18. The transparent flexible display device of claim 11, wherein the display element comprises an organic light emitting element.

19. The transparent flexible display device of claim 18, wherein the organic light emitting element comprises:
a pair of electrode layers facing each other; and
an intermediate layer disposed between the electrode layers.

20. The transparent flexible display device of claim 11, further comprising an encapsulating substrate facing the transparent polymer layer.
